(19) United States
(12) Patent Application Publication
(10) Pub. No.: US 2012/0119621 A1
(43) Pub. Date: May 17, 2012

(54) BENDING DEVICE FOR BENDING A PIEZOELECTRIC BENDER, PIEZOELECTRIC CONVERTER FOR CONVERTING MECHANICAL ENERGY INTO ELECTRICAL ENERGY, BY USING THE BENDING DEVICE, AND METHOD FOR CONVERTING MECHANICAL ENERGY INTO ELECTRICAL ENERGY

(76) Inventors: Alexander Frey, Munchen (DE); Ingo Kuhne, Munchen (DE)

(21) Appl. No.: 13/387,686

(22) PCT Filed: Jul. 9, 2010
(86) PCT No.: PCT/EP2010/059876

§ 371 Date: Jan. 27, 2012

(30) Foreign Application Priority Data
Jul. 27, 2009 (DE) 10 2009 034 610.4
Sep. 28, 2009 (DE) 10 2009 043 251.5

(51) Int. Cl. H01L 41/053; H02N 2/18

(52) U.S. Cl. 310/330; 310/339

(57) ABSTRACT

A workpiece having a bearing surface with at least one convex curvature and an opposing workpiece having an opposing bearing surface with a concave curvature essentially inverse to the convex curvature of the bearing surface are moved by a device relative to each other in such a manner that the convex curvature of the bearing surface can be guided into the concave curvature of the opposing bearing surface. To convert energy, a bending element, such as a disk bender, is located in a space between the bearing surface and the opposing bearing surface so that the movement of the workpiece and the opposing workpiece relative to each other results in the bending of the bending element. Mechanical energy can be converted into electrical energy with higher efficiency by using a disk bender. The workpieces and the bearing surfaces thereof are formed to provide overload protection.

### CROSS REFERENCE TO RELATED APPLICATIONS

This application is the U.S. national stage of International Application No. PCT/EP2010/059876, filed Jul. 9, 2010 and claims the benefit thereof. The International Application claims the benefit of German Patent Application Nos. 10 2009 034 610.4 filed on Jul. 27, 2009 and 10 2009 043 251.5 filed on Sep. 28, 2009. All three applications are incorporated by reference herein in their entirety.

### BACKGROUND

Described below is a bending apparatus for bending a piezoelectric bending element. A piezoelectric energy converter for conversion of mechanical energy to electrical energy with the aid of the bending apparatus, and a method for conversion of the mechanical energy to electrical energy are also specified.

The sensor system and peripheral circuits (signal processing, RF radio) must be supplied with power for operation. Typically, this power is made available from a battery. At the moment, there is a large amount of research and development work with the aim of replacing the battery by an autonomous power supply. It is necessary to use existing environmental energy for this purpose, and to convert this to an electrically usable form.

Various techniques are being investigated relating to such autonomous power systems. In this case, an energy converter in the form of a piezoelectric energy converter has been found to be particularly advantageous. In the piezoelectric energy converter, a mechanical force is introduced into a piezoelectric element, for example a piezoelectric bending converter. The mechanical force which is introduced leads to bending of the bending element. This results in charge separation, which can be utilized to obtain electrical energy.

### SUMMARY

An aspect is to indicate a possible way to allow mechanical energy to be converted efficiently to electrical energy by use of the piezoelectric effect.

To achieve this aspect, a bending apparatus is specified for bending a piezoelectric bending element having a workpiece with a contact surface with at least one convex curvature, a mating workpiece having a mating contact surface with a concave curvature which is essentially the inverse of the convex curvature of the contact surface, and an apparatus for relative movement of the workpiece and of the mating workpiece relative to one another such that the convex curvature of the contact surface can be guided into the concave curvature of the mating contact surface. In this case, the bending element can be arranged in an intermediate space between the contact surface and the mating contact surface such that the relative movement of the workpiece and of the mating workpiece results in bending of the bending element.

A piezoelectric energy converter for conversion of mechanical energy to electrical energy by introduction of a mechanical force, which is caused by the mechanical energy, into at least one piezoelectric element having the bending apparatus and a piezoelectric bending element is also specified. In this case, the piezoelectric bending element is arranged in the intermediate space between the contact surface and the mating contact surface such that the relative movement between the workpiece and the mating workpiece leads to bending of the piezoelectric bending element, and the bending allows the mechanical force to be introduced into the piezoelectric bending element.

According to a further aspect, a method is specified for conversion of mechanical energy to electrical energy using the energy converter by movement of the workpiece and of the mating workpiece with respect to one another.

The piezoelectric bending element has a layer sequence of an electrode layer, piezoelectric layer and further electrode layer. A plurality of such layer sequences can be stacked on top of one another in this way, thus resulting in a multilayer structure having electrode layers and piezoelectric layers which are arranged alternately and are stacked one on top of the other.

The electrode material of the electrode layers may include widely differing metals or metal alloys. Examples for the electrode material are platinum, titanium and/or platinum/titanium alloy. Non-metallic, electrically conductive materials are also feasible.

The piezoelectric layer may likewise include widely differing materials. Examples of this are piezoelectric ceramic materials such as lead-zirconate titanate (PZT), zinc oxide (ZnO) and aluminum nitride (AlN). Piezoelectric organic materials such as polyvinylidenedifluoride (PVDF) or polytetrafluoroethylene (PTFE) are likewise feasible.

The layer thicknesses of the electrode layers are a few micrometers. The layer thicknesses of the piezoelectric layer are several micrometers up to a millimeter.

The energy converter may have lateral dimensions from a few millimeters to several centimeters. This also applies to the lateral dimensions of the membrane. The layer thicknesses of the layers of the membrane extend from a few micrometers to several millimeters.

The dimensions of the contact surface and of the mating contact surface are also in this range. In this case, the contact surface and the mating contact surface are preferably essentially of the same size. This means that there may also be discrepancies of up to 10% with respect to the size of the contact surfaces. However, it is also feasible for one of the contact surfaces to be considerably larger than the other.

It is advantageous for the curvature and the mating curvature to have a curvature of essentially the same magnitude. The magnitude results in the curvatures having virtually the same radii of curvature. In this case, a discrepancy of up to 10% is feasible. Radii of curvature of the same magnitude lead to the capability to arrange the convex curvature such that it fits accurately in the concave mating curvature. The convex curvature is introduced into the recess in the concave mating curvature by the relative mutual movement of the workpiece and of the mating workpiece.

The bending element may be a traditional bending converter with a rectangular base surface (bending beam). In particular, the piezoelectric bending element is a piezoelectric bending converter with a circular base surface. The piezoelectric bending element is a circular disk bender. The circular disk bender is in principle suitable for obtaining as much electrical energy as possible from mechanical energy. This is based on the geometry of the circular disk bender being suitable for conversion.

The following relationships result from the geometric parameters of the bending beam, specifically the length l, the width b, the overall thickness hₚ, r, s and rₕ, and the cylindrical shell shape which results from the bending (see FIG. 3):

$$\begin{matrix}l = \frac{arctan ( \frac{2 \cdot {r}_{h}}{s} ) \cdot ( 4 \cdot {r}_{h}^{2} + {s}^{2} )}{2 \cdot {r}_{h}} \\ where {r}_{h} = r - \sqrt{{r}^{2} - {( \frac{s}{2} )}^{2}} , s = 2 \cdot \sqrt{{r}^{2} - {( r - {r}_{h} )}^{2}} & ( 1 ) \\ {r}_{h} = r - \sqrt{{r}^{2} - {( \frac{s}{2} )}^{2}} & ( 2 )\end{matrix}$$

The maximum mechanical stress is calculated from this as follows:

$$Δ σ ( x ) = {E}_{p} \cdot S = {E}_{p} \cdot \frac{{u}_{r +} - {u}_{r}}{{u}_{r}} = {E}_{p} \cdot \frac{1}{2} \frac{{h}_{p}}{r} \qquad ( 4 )$$

In this case, Eₚ is Young's modulus (E modulus) and S is the mechanical strain. The achievable electrical energy and electrical voltage are given by:

$$\begin{matrix}{W}_{invention} = \frac{1}{2} \cdot \frac{{d}^{2}}{ɛ} \cdot \frac{{h}_{p}}{2} \cdot b \cdot 2 \cdot {\int }_{0}^{l} Δ {σ}^{2} ( x ) d x = \frac{{d}^{2}}{ɛ} \cdot \frac{{h}_{p}}{2} \cdot b \cdot l \cdot Δ {σ}^{2} = \cdot \frac{1}{8} \cdot \frac{{d}^{2}}{ɛ} \cdot {E}_{p}^{2} \cdot \frac{{h}_{p}^{3} \cdot b \cdot l ( r , s )}{{r}^{2}} & ( 5 ) \\ {V}_{invention} = \frac{1}{2} \frac{d}{{ɛ}_{p}} \cdot {h}_{p} \cdot Δ σ ( x ) = \frac{1}{4} \frac{d}{{ɛ}_{p}} \cdot {E}_{p} \cdot \frac{{h}_{p}^{2}}{r} & ( 6 )\end{matrix}$$

In comparison to a known bending converter in the form of a beam, this means six times more electrical energy and a voltage which is twice as high.

Furthermore, particularly in the case of a circular disk bender, it is advantageous for the convex curvature and/or the concave curvature to have a circular foot circumference, which is matched to the size of the circular disk bender. The circular disk bender is arranged between the two workpieces. The relative movement of the workpiece and mating workpiece with respect to one another leads to bending of the circular disk bender. This leads to efficient conversion of mechanical energy to electrical energy. At the same time, this ensures that the circular disk bender is not mechanically overloaded. This is because the mating workpiece acts as a stop. The accurate fit between the curvature, the mating curvature and the circular disk bender ensures that the circular disk bender is not destroyed during bending.

The bending converter can be arranged—without being held—in the intermediate space between the workpiece and the mating workpiece. However, the bending converter is preferably fixed to the workpiece and/or to the mating workpiece before and/or during the bending process. In particular, for this purpose, the bending element is connected to the workpiece at a connection point of the contact surface of the workpiece, and/or is connected to the mating workpiece by an integral material joint at a connection point of the mating contact surface of the mating workpiece. By way of example, the integral material joint has a soldered joint. It is particularly advantageous for the integral material joint to have an adhesive. The bending converter is adhesively bonded to the curvature of the workpiece. An adhesive joint such as this can be produced very easily, and can be produced permanently. Furthermore, this does not lead to any thermal loading of the workpiece and/or of the bending converter during production of the integral material joint.

According to one particular refinement, the workpiece has a holding area for holding the mating workpiece. In this case, the workpiece and the mating workpiece are connected to one another via a bearing such that the workpiece and the mating workpiece can move relative to one another. The bearing acts as an apparatus for relative mutual movement of the workpiece and of the mating workpiece. By way of example, the bearing is a journal bearing.

The bending device may be used in autonomous power systems for conversion of mechanical energy to electrical energy.

In summary, the following advantages are provided:
In particular when using a circular disk bender, more electrical energy can be achieved from the same mechanical force than in the case of known bending converters in the form of a beam.
Constant power delivery is possible from a threshold value for the mechanical force.
A higher electrical voltage is possible than in the case of known bending converters.
This results in a constant output voltage from the threshold value for the mechanical force.
Overload protection can be ensured by suitable design measures.

### BRIEF DESCRIPTION OF THE DRAWINGS

These and other aspects and advantages will become more apparent and more readily appreciated from the following description of exemplary embodiment, taken in conjunction with the accompanying drawings which are schematic and do not represent scale drawings.

FIG. 1 is a side cross section through a piezoelectric energy converter without any external force influence,

FIG. 2 is a side cross section through the energy converter with external force influence,

FIG. 3 illustrates, schematically, a circular disk bender with two piezoelectric layers.

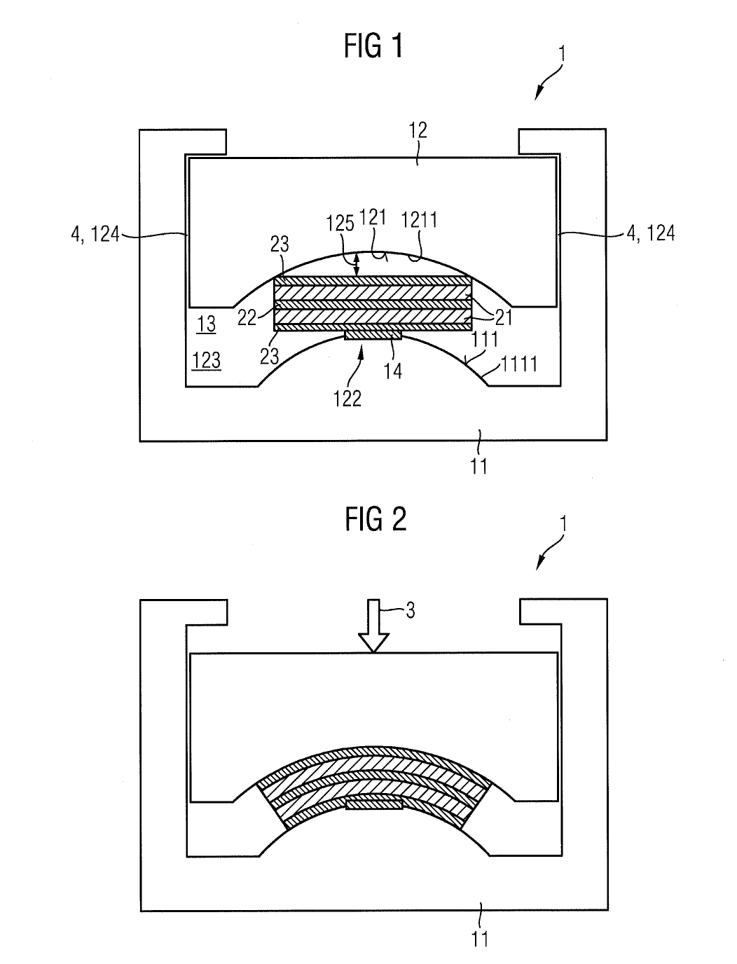

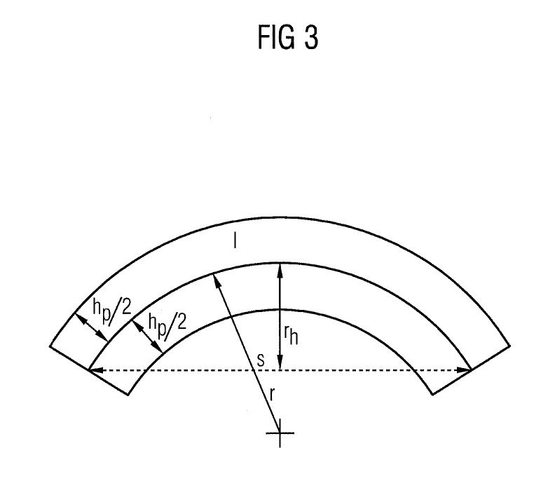

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

The bending apparatus 1 for bending the piezoelectric bending element 2 has a workpiece 11 with a contact surface 111. The contact surface has convex curvature 1111 with a corresponding curvature (cylindrical shape). The convex curvature has a circular foot circumference 1113.

Furthermore, the bending apparatus 1 has a mating workpiece 12 with concave curvature 1211. The concave curvature has a curvature whose magnitude corresponds essentially to that of the curvature of the convex curvature. A foot circumference 1213 of the concave curvature is also circular. The contact surface of the workpiece and the mating contact surface of the mating workpiece are of the same size. Because the curvatures are the same, the contact surface and the mating contact surface can be arranged such that they fit accurately into one another.

The piezoelectric bending element is a circular disk bender with a circular base surface. In an alternative embodiment to this, the piezoelectric bending element has a rectangular base surface. The piezoelectric bending element is a traditional bending beam.

Irrespective of the configuration of the base surface, the piezoelectric bending element has a layer structure with two piezoelectric layers 21 and an inner electrode 22 arranged between the piezoelectric layers. Two outer electrodes 23 form the termination.

The piezoelectric bending converter is connected to the contact surface via an integral material joint 14 at the connection point 122 of the contact surface. The integral material joint has an adhesive. The piezoelectric bending element is The mating workpiece is located in a holding area 123 in the workpiece. In this case, the workpiece and the mating workpiece are connected to one another via a bearing 124 such that the mating workpiece can be moved with respect to the workpiece in the holding area such that it is possible to vary a distance 125 between the contact surface and the mating contact surface. The contact surface and the mating contact surface can be moved relative to one another.

The process for conversion of mechanical energy to electrical energy is as follows: movement of the mating workpiece in the direction of the workpiece as a result of an external mechanical force 3 leads to bending of the bending converter. This leads to charge separation because of the piezoelectric effect. The separated electrical charge can be used to obtain electrical energy. In this case, the workpiece with the contact surface and the mating workpiece with the mating contact surface act as a stop. The bending converter cannot be overloaded.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-12. (canceled)

13. A bending apparatus for bending a piezoelectric bending element, comprising:
a workpiece with a contact surface having at least one convex curvature;
a mating workpiece having a mating contact surface with a concave curvature substantially inverse of the at least one convex curvature of the contact surface; and
an apparatus causing relative movement of the workpiece and the mating workpiece relative to each other to guide the convex curvature of the contact surface into the concave curvature of the mating contact surface and, when the piezoelectric bending element is arranged in an intermediate space between the contact surface and the mating contact surface, the relative movement of the workpiece and the mating workpiece bends the piezoelectric bending element.

14. The bending apparatus as claimed in claim 13, wherein the contact surface and the mating contact surface have a substantially same size.

15. The bending apparatus as claimed in claim 14, wherein the curvature and the mating curvature have a curvature of a substantially same magnitude.

16. The bending apparatus as claimed in claim 15, wherein the convex curvature and the concave curvature have a circular foot circumference.

17. The bending apparatus as claimed in claim 16, wherein the piezoelectric bending element is connected to at least one of the workpiece at a connection point of the contact surface of the workpiece, and the mating workpiece by an integral material joint at a connection point of the mating contact surface of the mating workpiece.

18. The bending apparatus as claimed in claim 17, wherein the integral material joint has an adhesive.

19. The bending apparatus as claimed in claim 18,
wherein the workpiece has a holding area for holding the mating workpiece, and
wherein the bending apparatus further comprises a bearing connecting the workpiece to the mating workpiece while allowing the relative movement of the workpiece and the mating workpiece.

20. The bending apparatus as claimed in claim 13, wherein at least one of the convex curvature and the concave curvature has a circular foot circumference.

21. A piezoelectric energy converter for conversion of mechanical energy to electrical energy by introduction of a mechanical force, caused by the mechanical energy, into at least one piezoelectric bending element, comprising:
a bending apparatus including
a workpiece with a contact surface having at least one convex curvature;
a mating workpiece having a mating contact surface with a concave curvature substantially inverse of the at least one convex curvature of the contact surface; and
a movement apparatus causing relative movement of the workpiece and the mating workpiece relative to each other to guide the convex curvature of the contact surface into the concave curvature of the mating contact surface; and
a piezoelectric bending element that when arranged in an intermediate space between the contact surface and the mating contact surface, the relative movement between the workpiece and the mating workpiece bends the piezoelectric bending element, thereby introducing the mechanical force into the piezoelectric bending element.

22. The piezoelectric energy converter as claimed in claim 21, wherein the piezoelectric bending element is a piezoelectric bending converter with a circular base surface.

23. The piezoelectric energy converter as claimed in claim 22, wherein the piezoelectric bending element is connected to the workpiece by an integral material joint of the workpiece.

24. The piezoelectric energy converter as claimed in claim 23, wherein the integral material joint has an adhesive.

25. A method for conversion of mechanical energy to electrical energy using a piezoelectric energy converter including a piezoelectric bending element, a bending apparatus, a workpiece with a contact surface having at least one convex curvature, and a mating workpiece having a mating contact surface with a concave curvature substantially inverse of the at least one convex curvature of the contact surface, comprising:
arranging the piezoelectric bending element in an intermediate space between the contact surface of the workpiece and the mating contact surface of the mating workpiece; and
operating the bending apparatus, after said arranging, to cause relative movement of the workpiece and the mating workpiece relative to each other to guide the convex curvature of the contact surface into the concave curvature of the mating contact surface, thereby bending the piezoelectric bending element.
